(19) United States
(12) Patent Application Publication
(10) Pub. No.: US 2006/0044769 A1
(43) Pub. Date: Mar. 2, 2006

(54) RFID device with magnetic coupling

(76) Inventors: Ian J. Forster, Chelmsford (GB); Thomas Craig Weakley, Simpsonville, SC (US)

Correspondence Address: Jonathan A. Platt;Renner, Otto, Boisselle & Sklar, LLP, Nineteenth Floor, 1621 Euclid Avenue, Cleveland, OH, 44115-2191, US

(21) Appl. No.: 10/931,863

(22) Filed: Sep. 1, 2004

(51) Int. Cl. H05K 7/06

(52) U.S. Cl. 361/760; 361/782; 361/783

(57) ABSTRACT

An RFID device, such as an RFID tag or label, includes a magnetic coupler between an interposer or strap, and an antenna. The interposer or strap includes a transponder chip and an interposer magnetic coupling element that is operatively coupled to the transponder. An antenna portion magnetic coupling element is operatively coupled to the antenna. The magnetic coupling element s together constitute a magnetic coupler that is used to magnetically couple the transponder chip of the interposer to the RFID antenna. A high permeability material may be used to enhance the magnetic coupling between the magnetic coupling elements. The magnetic coupling elements single-turn conductive loops or multiple-turn coils. The magnetic coupler may function as a transformer, with the voltage across the antenna transformed to a different voltage across the transponder chip, and vice versa.

### BACKGROUND OF THE INVENTION

1. Field of the Invention

This invention relates to the field of radio frequency identification (RFID) tags and labels.

2. Description of the Related Art

RFID tags and labels have a combination of antennas and analog and/or digital electronics, which may include for example communications electronics, data memory, and control logic. RFID tags and labels are widely used to associate an object with an identification code. For example, RFID tags are used in conjunction with security-locks in cars, for access control to buildings, and for tracking inventory and parcels. Some examples of RFID tags and labels appear in U.S. Pat. Nos. 6,107,920, 6,206,292, and 6,262,292, all of which this application incorporates by reference.

RFID tags and labels include active tags, which include a power source, and passive tags and labels, which do not. In the case of passive tags, in order to retrieve the information from the chip, a “base station” or “reader” sends an excitation signal to the RFID tag or label. The excitation signal energizes the tag or label, and the RFID circuitry transmits the stored information back to the reader. The “reader” receives and decodes the information from the RFID tag. In general, RFID tags can retain and transmit enough information to uniquely identify individuals, packages, inventory and the like. RFID tags and labels also can be characterized as to those to which information is written only once (although the information may be read repeatedly), and those to which information may be written during use. For example, RFID tags may store environmental data (that may be detected by an associated sensor), logistical histories, state data, etc.

Still other RFID devices and methods for manufacturing RFID labels are disclosed in U.S. Patent Application Publication No. U.S. 2001/0053675 by Plettner, which is incorporated herein by reference in its entirety. The devices include a transponder comprising a chip having contact pads and at least two coupling elements, which are conductively connected with the contact pads. The coupling elements are touch-free relative to each other and formed in a self-supported as well as a free-standing way and are essentially extended parallel to the chip plane. The total mounting height of the transponder corresponds essentially to the mounting height of the chip. The size and geometry of the coupling elements are adapted for acting as a dipole antenna or in conjunction with an evaluation unit as a plate capacitor. Typically, the transponders are produced at the wafer level. The coupling elements can be contacted with the contact pads of the chip directly at the wafer level, i.e., before the chips are extracted from the grouping given by the wafer.

In many applications, it is desirable to reduce the size of the electronics as small as possible. In order to interconnect very small chips with antennas in RFID inlets, it is known to use a structure variously called “interposers”, “straps”, and “carriers” to facilitate inlay manufacture. Interposers include conductive leads or pads that are electrically coupled to the contact pads of the chips for coupling to the antennas. These pads provide a larger effective electrical contact area than ICs precisely aligned for direct placement without an interposer. The larger area reduces the accuracy required for placement of ICs during manufacture while still providing effective electrical connection. IC placement and mounting are serious limitations for high-speed manufacture. The prior art discloses a variety of RFID interposer or strap structures, typically using a flexible substrate that carries the interposer's contact pads or leads.

One type of prior art RFID inlet manufacture using interposers is disclosed in European Patent Application EP 1039543 A2 to Morgan Adhesives Company (“Morgan”). This patent application discloses a method of mounting an integrated circuit chip (IC) using an interposer connected across a gap between two thin conductive film sections of a conductive film antenna. The interposer comprises a thin substrate having two printed conductive ink pads. This method is said to be suitable for mass production of radio frequency identification tags (RFIDs) by mounting ICs on interposers that are then physically and electrically connected to the antenna sections using a pressure sensitive conductive adhesive. The pressure sensitive conductive adhesive provides a direct electrical connection between the interposer contact pads and the antenna sections.

Another type of prior art RFID inlet manufacture using interposers is based on a technique for manufacturing microelectronic elements as small electronic blocks, associated with Alien Technology Corporation (“Alien”) of Morgan Hill California. Alien has developed techniques to manufacture small electronic blocks, which it calls “NanoBlocks”, and then deposit the small electronic blocks into recesses on an underlying substrate. To receive the small electronic blocks, a planar substrate 200 (FIG. 1) is embossed with numerous receptor wells 210. The receptor wells 210 are typically formed in a pattern on the substrate. For instance, in FIG. 1 the receptor wells 210 form a simple matrix pattern that may extend over only a predefined portion of the substrate, or may extend across substantially the entire width and length of the substrate, as desired. Alien has a number of patents on its technique, including U.S. Pat. Nos. 5,783,856; 5,824,186; 5,904,545; 5,545,291; 6,274,508; and 6,281,038, all of which the present application incorporates by reference. Further information can be found in Alien's Patent Cooperation Treaty publications, including WO 00/49421; WO 00/49658; WO 00/55915; WO 00/55916; WO 00/46854 and WO 01/33621, all of which this application incorporates by reference in their entireties.

Alien's NanoBlock technology is adapted to interposer manufacture for producing RFID inlets in U.S. Pat. No. 6,606,247. A carrier substrate or interposer is coupled to an IC that is recessed below a surface of the interposer. The interposer further includes first and second carrier connection pads that interconnect with the IC using metal connectors. A planar antenna substrate carries first antenna sections with respective first and second receiving connection pads. The carrier substrate is coupled to the antenna substrate using the carrier connection pads and receiving connection pads. In contrast to the interposer of Morgan's European publication EP 1039543 A2 in which the IC is mounted above the interposer contact pads at the surface of the interposer substrate, in U.S. Pat. No. 6,606,247 the chips are retained in recesses in the interposer substrate, and the carrier connection pads are formed above the IC. However, both EP 1 039 543 A2 and U.S. Pat. No. 6,606,247 share the feature that the interposer or strap pads are directly electrically connected to the antenna sections using conductive adhesive.

Another problem to be solved in producing inlays using interposers is the reliable high speed mechanical and electrical coupling of the interposers (and interposer leads) to antennas. The present invention, in contrast to Morgan's EP 1 039 543 A2 and Alien's U.S. Pat. No. 6,606,247, uses a non-conductive adhesive to mechanically couple the interposer leads to the antenna sections. Non-conductive adhesives can facilitate high speed production in comparison to conductive adhesives, due to reduction of cure time requirements and production cycle times. However, since the adhesive is not electrically conductive, another mechanism (besides electrical conduction by the adhesive) must be provided to electrically couple the interposer leads to the antenna sections.

From the foregoing it will be seen that room exists for improvements in RFID tags and methods of assembling such tags.

### SUMMARY OF THE INVENTION

According to an aspect of the invention, a transponder chip of an RFID device is magnetically coupled to an antenna of the RFID device.

According to another aspect of the invention, an RFID device includes an interposer having a transponder chip, and an antenna. The transponder chip and the antenna are magnetically coupled via a magnetic coupler. According to an embodiment of the invention, the magnetic coupler includes coupling elements that are electrically coupled to the transponder chip and the antenna, respectively.

According to still another aspect of the invention, an RFID device includes a magnetic coupler that magnetically couples an antenna and a transponder chip together, wherein the magnetic coupler functions as a transformer, altering the voltage of a signal transferred between the antenna and the transponder chip.

According to a further aspect of the invention, an RFID device includes: an antenna portion that includes an antenna; an interposer having a transponder chip; and a magnetic coupler magnetically coupling the antenna and the chip.

To the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

In the annexed drawings, which are not necessarily according to scale:

FIG. 1 is a schematic diagram of an RFID device in accordance with the present invention;

FIG. 2 is an oblique view of an interposer for use as part of the RFID device of FIG. 1;

FIG. 3 is a plan view of an antenna portion for use with the RFID device of FIG. 1;

FIG. 4 is a plan view of part of an alternate embodiment antenna portion, which utilizes a dipole antenna;

FIG. 5 is a plan view of part of another alternate embodiment antenna portion, which utilizes a spiral antenna;

FIG. 6 is a plan view showing one possible coupling of an RFID device in accordance with the present invention;

FIG. 7 is a plan view showing an antenna portion having a multi-turn conductive loop or coil, for use in an RFID device in accordance with the present invention;

FIG. 8 is a plan view showing one embodiment of an antenna portion with a conductive element on one major face and an antenna on an opposite major face, with a direct electrical coupling between the two, for use in an RFID device in accordance with the present invention; and

FIG. 9 is a plan view showing one embodiment of an antenna portion with a conductive element on one major face and an antenna on an opposite major face, with a capacitive coupling between the two, for use in an RFID device in accordance with the present invention.

### DETAILED DESCRIPTION

An RFID device, such as an RFID tag or label, includes a magnetic coupler between an interposer or strap, and an antenna. The interposer or strap includes a transponder chip and an interposer magnetic coupling element that is operatively coupled to the transponder. An antenna portion magnetic coupling element is operatively coupled to the antenna. The magnetic coupling elements together constitute a magnetic coupler that is used to magnetically couple the transponder chip of the interposer to the RFID antenna. A high permeability material may be used to enhance the magnetic coupling between the magnetic coupling elements. The magnetic coupling elements may be conductive loops. The conductive loops may be single-turn conductive loops. Alternatively, one or both of the conductive loops may have multiple turns, thus being conductive coils. The use of multiple-turn conductive loops or coils allows the magnetic coupler to function as a transformer, with the voltage across the antenna transformed to a different voltage across the transponder chip, and vice versa. The magnetic coupler may have other advantageous characteristics in addition to enabling transformation of voltage, such as protecting the transponder chip against static discharge, or allowing the RFID device to operate in a strong electromagnetic environment.

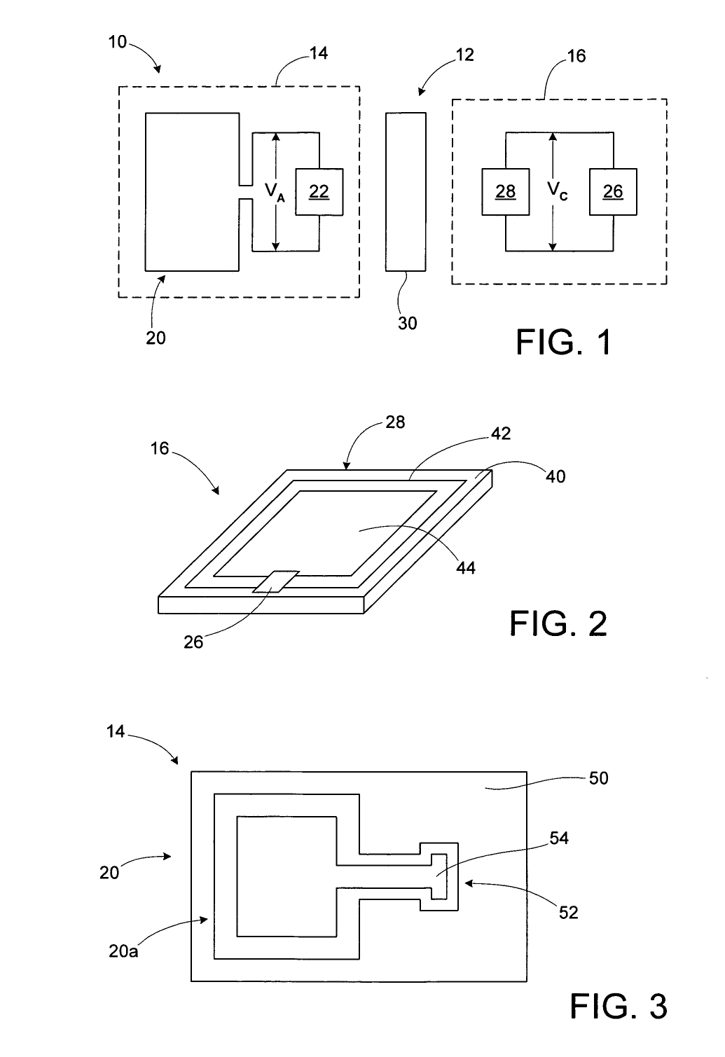

FIG. 1 shows an RFID device 10 that includes a magnetic coupler 12 operatively coupling together an antenna portion 14 and an interposer 16. The antenna portion 14 includes an antenna 20 and an antenna portion magnetic coupling element 22. The antenna 20 is electrically coupled to the magnetic coupling element 22. The electrical coupling between the antenna 20 and the antenna portion magnetic coupling element 22 may be a direct electrical (conductive) coupling, or may be a non-direct reactive coupling, such as capacitive coupling. The antenna 20 may be any of a variety of suitable antennas for receiving and/or sending signals in interaction with an RFID communication device such as a reader.

The interposer 16 includes a transponder chip 26, and an interposer magnetic coupling element 28 that is electrically coupled to the transponder chip 26. The coupling between the transponder chip 26 and the interposer magnetic coupling element 28 may be a direct electrical contact, or may include certain types of reactive coupling, such as capacitive coupling.

The transponder chip 26 may include any of a variety of suitable electrical components, such as resistors, capacitors, inductors, batteries, memory devices, and processors, for providing suitable interaction, through the antenna 20 (FIG. 1), with an external device. It will be appreciated that a large variety of transponder chips for RFID devices are widely known. The term “transponder chip” is intended to encompass the broad range of such devices, which may vary widely in complexity and functionality.

The magnetic coupling elements 22 and 28 together constitute the magnetic coupler 12. The interaction of the magnetic coupling elements 22 and 28 allows transfer of energy between the antenna 20 and the transponder chip 26, via magnetic coupling. Magnetic coupling, as the term is used herein, refers to short-range transfer of energy by interaction of magnetic fields.

Magnetic coupling and/or capacitive coupling are referred to collectively herein as “reactive coupling,” in contrast to direct electrical coupling by electrically conductive material. References herein to magnetic, capacitive, or reactive coupling refer to coupling that is predominantly or primarily magnetic, capacitive, or reactive. It will be appreciated that coupling that is primarily magnetic may also include some capacitive coupling. Conversely, coupling that is primarily capacitive may also include some inductive (magnetic) coupling as a secondary coupling mechanism. Systems using primarily capacitive or magnetic coupling are referred to herein as utilizing reactive coupling. Capacitive, magnetic, or reactive coupling, as the terms are used herein, may also include some direct conductive coupling, albeit not as the primary type of electrical coupling.

The magnetic coupler 12 relies on short-range coupling within the RFID device 10 to transmit energy and/or signals between the antenna 20 and transponder chip 26. In contrast, primarily the antenna 20 is relied upon for long-range far-field RF coupling to devices outside the RFID device 10. The far field, as used herein, refers to a distance greater than on the order of 15 mm from an RF-energy emitting device, such as device that emits UHF RF energy. Coupling of an RFID device in the far field is also referred to as “long-range coupling.” The near field, where short-range coupling may occur, is defined as within on the order 15 mm from an RF-energy emitting device. A more precise boundary of between the near field and the far field may be λ/2π, where λ is the wavelength of the RF energy of the RF coupling. For RF of energy of 915 MHz, the boundary between the near field and the far field would be about 52 mm from the device, using this definition.

The magnetic coupling elements 22 and 28 may be such that any dimension of them is less than about one-tenth of a wavelength of the energy of signals being transmitted and received by the RFID device 10. Thus the magnetic coupling elements, by their size alone, may be unsuitable for long-range coupling.

As discussed further below, the magnetic coupling elements 22 and 28 may each include one or more conductive loops, that is, one or more loops of electrically-conductive material substantially surrounding non-conductive material. The coupling elements 22 and 28 may have the same number of turns of conductive material. Alternatively, the coupling elements 22 and 28 may have a different number of turns of conductive material. When the coupling elements 22 and 28 have different numbers of turns of conductive material, the voltage V_{A} across the antenna 20 may in general be different than the voltage V_{C} across the transponder chip 26. That is, with different numbers of turns in the two coupling elements 22 and 28, the magnetic coupler 12 may act as a transformer. In general, depending on the number of conductive turns in the respective coupling elements 22 and 28, the voltage V_{A} of the antenna 20 may be greater than, less than, or substantially the same as the voltage V_{C} across the transponder chip 26. Transforming the voltage across the magnetic coupler 12 may be beneficial in operation of the RFID device 10. For instance, in many RFID devices the rectifiers will not put out a voltage greater than peak-to-peak voltage of the applied input RF signal. By multiplying the voltage/impedance presented to the transponder chip 26, the operating range of the RFID device 10 may potentially be increased. This method of increasing the voltage V_{C} across the transponder chip 26 may be superior to other prior methods of increasing the voltage across a transponder chip. Such prior methods include use of a voltage multiplier circuit to increase the voltage across the transponder chip or a portion thereof, and increasing the impedance of an antenna. Inclusion of a voltage multiplier circuit or charge pump increases complexity, and may result in only a minor increase in voltage, on the order of 0.8 volts. Increasing the impedance of the antenna also has practical limitations, as there is a limit to how high the impedance of the antenna may be set without adversely affecting the efficiency of the antenna.

Referring again to FIG. 1, a high permeability material 30 may be placed in proximity to the magnetic coupling elements 22 and 28. Ferrites are an example of suitable materials for the high permeability material 30. Ferrites are ceramic materials, generally containing iron oxide combined with binder compounds such as nickel, manganese, zinc, or magnesium. Two major categories of binder compounds are manganese zinc (MnZn) and nickel zinc (NiZn).

The high permeability material 30 may be placed between the magnetic coupling elements 22 and 28, or elsewhere in proximity to the magnetic coupling elements 22 and 28. The high permeability material 30 may be used to increase and/or concentrate magnetic coupling between the magnetic coupling elements 22 and 28. The high permeability material 30 may increase the amount of flux transferred between the magnetic coupling elements 22 and 28. The high permeability material 30 may be in the form of any of a variety of layers or structures in proximity to the magnetic coupling portions or elements 22 and 28. For example, the high permeability material may be a coating on or in proximity to either or both of the magnetic coupling elements 22 and 28. One possibility for such a coating is ferrite particles contained in an organic binder, such as a pressure sensitive adhesive. Another possibility is ferrite particles (on the order of tens of nanometers to microns) in ink jet printable water-based inks. Alternatively, the high permeability material 30 may be incorporated into the substrate of either or both of the interposer 16 or the antenna portion 14, for example by being added in powder form as the substrate is formed. As a further alternative, the high permeability material 30, such as ferrite particles, may be incorporated into an adhesive or other bonding layer that is used to attach the interposer 16 to the antenna portion 14. Making the high permeability material 30 as part of the structure of the interposer 16, or as part of the mechanical coupling between the interposer 16 and the antenna portion 14, may advantageously concentrate the magnetic flux into the interposer 16 even when the interposer 16 is not optimally positioned. That is, the high permeability material 30 may aid in magnetic coupling of the magnetic coupling elements 22 and 28 even when the magnetic coupling element 22 and 28 are not optimally positioned relative to one another. This may make the RFID device 10 tolerant to a large range of less-than-optimal relative positions of the interposer 16 and the antenna portion 14. It will be appreciated that this tolerance to mis-positioning of the interposer 16 may lead to reduced cost and/or improved performance in any of a number of ways. For example, it may be possible to use less costly methods of placing the interposer 16, with a greater acceptable range of placement positions. In addition, rejection rates may be reduced and/or performance of the RFID device 10 may be improved, due to the presence of the high permeability material 30.

Another potential advantage of the high permeability material 30 is that it may prevent damage to the transponder chip 26 by effectively de-tuning the RFID device 10 when a strong input signal is received by the antenna 20. As background, it is commonly appreciated that it is desirable for the antenna and the transponder chip to be optimally “tuned” such that the impedance of the two are complex conjugates of each other (substantially equal resistance and opposite reactance). In general, the characteristics of the magnetic coupler 12 may be taken into account in properly tuning the RFID device 10 so as to match resistance and impedance between the antenna 20 and the transponder chip 26. The presence of the high permeability material 30 may limit the amount of energy that may be transferred through the magnetic coupler 12 from the antenna 20 to the transponder chip 26. This is because an extremely strong signal incident on the antenna 20 may cause a change in permeability of the high permeability material 30. This change in permeability may effectively de-tune the RFID device so as to reduce the efficiency of the magnetic coupler 12. The de-tuning inhibits energy transfer across the magnetic coupler 12. The result may be a mechanism that advantageously prevents overloading of the transponder chip 26. It will be appreciated that it is desirable to prevent overload of the transponder chip 26 since such overloading may cause damage to or failure of the transponder chip 26, leading to adverse effects upon the performance of the RFID device 10.

The RFID device 10, and specifically the magnetic coupler 12, may be configured such that the effective induction presented to the transponder chip 26 by the magnetic coupling element 28 is such that the induction is equal and opposite to the capacitance of the transponder chip 26. Such an arrangement results in a resonant structure consisting of the antenna 20, the magnetic coupler 12, and the transponder chip 26. Such a resonant structure arrangement allows for more efficient and more effective transfer of energy between the antenna 20 and the transponder chip 26.

It will be appreciated that the RFID device 10 may include additional layers and/or structures. For example, the RFID device 10 may include a web or sheet of material used to support and protect an RFID inlay stock that includes the antenna portion 14, and/or to provide usable form factors and surface properties (e.g. printability, adhesive anchorage, weatherability, cushioning, etc.) for specific applications. For example, a suitable top web or facestock layer for carrying printing may be utilized. Suitable materials for the facestock include, but are not limited to, metal foils, polymer films, paper, textiles, and combinations thereof. Textiles include woven and non-woven fabrics made of natural or synthetic fibers. The materials can be single-layered paper or film or they can be multi-layered constructions. The multi-layered constructions or multi-layered polymeric films can have two or more layers, which can be joined by coextrusion, lamination, or other processes. The layers of such multi-layered constructions or multi-layered polymeric films can have the same composition and/or size or can have different compositions or sizes.

Turning now to FIG. 2, details are given of one embodiment of the interposer 16. The interposer 16 includes an interposer substrate 40 upon which the interposer magnetic coupling element 28, is located. An interposer conductive loop 42 is electrically coupled to the transponder chip 26. The transponder chip 26 may be physically attached to the interposer substrate 40, and/or to the interposer conductive loop 42. The physical attachment may be an adhesive attachment, or may be by another suitable attachment method.

The conductive loop 42 substantially surrounds a non-conductive area 44. By substantially surrounding the non-conductive area 44, the conductive loop 42 is suitably capable of interacting with the antenna portion magnetic coupling element 22 (FIG. 1), so as to magnetically couple together the antenna 20 and the transponder chip 26.

The conductive loop 42 is shown in FIG. 2 as having a generally rectangular shape. This is only one example of a large variety of suitable shapes for the interposer conductive loop 42. The interposer conductive loop 42 may alternatively be generally circular, for example. The ends of the conductive loop 42 are electrically coupled to respective contacts of the transponder chip 26. It will be appreciated that this provides a short circuit between the contacts of the transponder chip 26. Short circuiting together the contacts may advantageously protect the transponder chip 26 from certain electrical events, such as from damage due to static electricity. The short circuiting provided by the conductive loop 42 prevents static electricity from imposing a large voltage difference across the two contacts of the transponder chip 26. Thus some types of damage to the transponder chip 26 may be avoided.

Examples of suitable materials for the interposer substrate 40 include, but are not limited to, high Tg polycarbonate, polyethylene terephthalate (PET), polyarylate, polysulfone, a norbornene copolymer, poly phenylsulfone, polyetherimide, polyethylenenaphthalate (PEN), polyethersulfone (PES), polycarbonate (PC), a phenolic resin, polyester, polyimide, polyetherester, polyetheramide, cellulose acetate, aliphatic polyurethanes, polyacrylonitrile, polytrifluoroethylenes, polyvinylidene fluorides, HDPEs, poly(methyl methacrylates), a cyclic or acyclic polyolefin, or paper.

The conductive loop 42 may be any of a wide variety of conductive materials, placed on the interposer substrate 40 in any of a variety of suitable ways. The conductive loop 42 may be formed of conductive ink printed on or otherwise deposited on the interposer substrate 40. Alternatively, the conductive loop 42 may be an etched conductive material that is adhesively or otherwise adhered to the interposer substrate 40. Other possible alternatives for formation of the conductive loop 42 include deposition methods such as vapor deposition or sputtering, and plating methods such as electroplating.

It will be appreciated that it would be desirable that the interposer conductive loop 42 be of a material that has a low electrical resistance. The higher the resistance of the material of the conductive loop 42, the more energy that is dissipated within the conductive loop 42, and the lower the amount of energy that is forwarded to the transponder chip 26. Thus the conductive loop 42 may be configured such that its resistance is less than about 10% of the input impedance of the interposer 16.

Turning now to FIG. 3, some details of one configuration of the antenna portion 14 is shown. The antenna portion 14 includes an antenna substrate 50. The antenna 20 and an antenna portion conductive loop 52 are formed upon or attached to the antenna substrate 50. The antenna portion conductive loop 52 surrounds a non-conductive area 54. The antenna portion conductive loop 52 is configured to be the antenna portion magnetic coupling element 22 that couples to the interposer magnetic coupling element 28 (FIG. 1) as part of the magnetic coupler 12 (FIG. 1). The antenna substrate 50 may be made of material similar to that of the interposer substrate 40 (FIG. 2). The antenna 20 and the antenna portion conductive loop 52 may be made of material and by methods similar to those described above with regard to the interposer conductive loop 42 (FIG. 2). The antenna 20 and the antenna portion conductive loop 52 may be formed by the same process in a single step. Alternatively, the antenna 20 and the conductive loop 52 may be formed in different steps and/or by different processes.

As shown in FIG. 3, the antenna 20 may be coupled to the antenna portion conductive loop 52 by direct electrical coupling. It will be appreciated that the electrical coupling between the antenna 20 and the antenna portion coupling loop 52 may be made by other mechanisms such as capacitive coupling.

The antenna portion conductive loop 52 may have a size and shape similar to that of the interposer conductive loop 42 (FIG. 2). Alternatively the conductive loops 42 and 52 may have different suitable shapes. The range of suitable shapes for the antenna portion conductive loop 52 may be as broad as that for the interposer conductive loop 42.

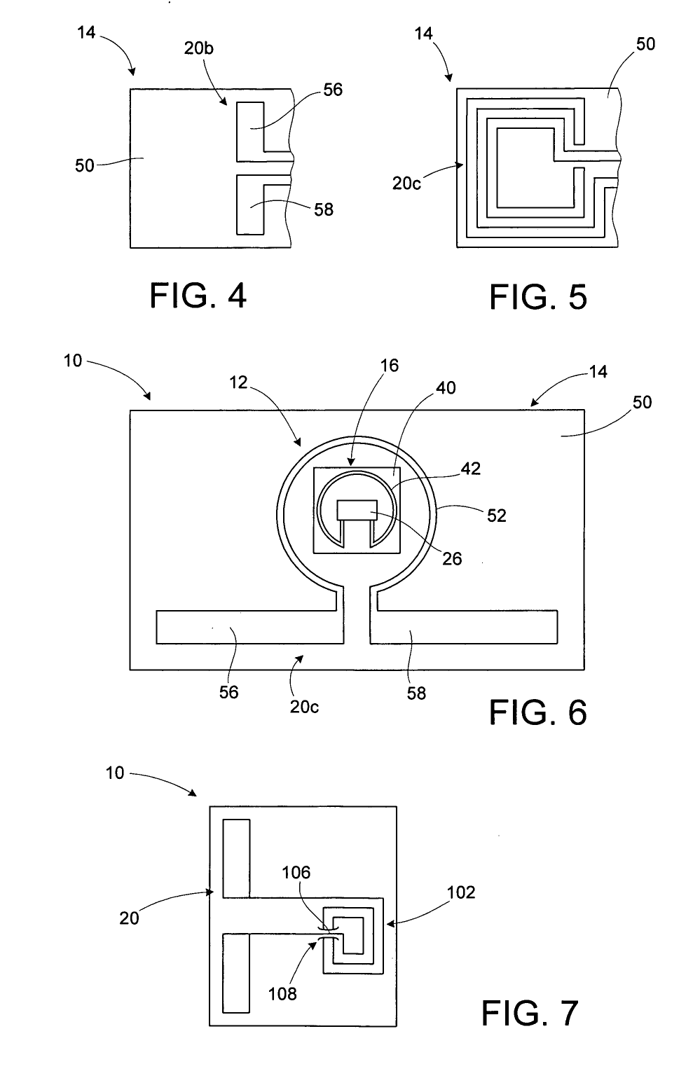

The antenna 20 shown in FIG. 3 is a loop antenna 20a. It will be appreciated that many other suitable configurations are possible for the antenna 20. Examples of other suitable configurations include a dipole antenna 20b with antenna elements 56 and 58, shown in FIG. 4, and a spiral antenna 20c, shown in FIG. 5. Other types of suitable antennas include slot antennas, patch antennas, and various hybrid antenna types. The mechanism for generating the magnetic field in the magnetic coupler 12 (FIG. 1) may vary based on the antenna type or configuration.

FIG. 6 shows another configuration of the RFID device 10, where the conductive loop 42 and the transponder chip 26 of the interposer 16, are located within the antenna portion conductive loop 52. The antenna portion conductive loop 52 is directly electrically connected to the antenna elements 56 and 58 of the dipole antenna 20b. In order for the RFID device 10 to form a resonant structure, it is desirable that the dipole antenna 20b presents to the antenna portion conductive loop 52 a complex impedance with a resistance substantially equal to a transformed impedance as the transponder chip 26, and a reactance substantially equal and opposite to the reactance of the antenna portion conductive loop 52. For the interposer 16, the inductance of the interposer conductive loop may be chosen to resonate with the capacitance of the transponder chip 26.

The transponder chip 26 has been described above as a chip having two contacts that are coupled to the magnetic coupling element 28. It will be appreciated that suitable modifications may be made for transponder chips that require or utilize three or more conductive contacts, such as for achieving greater orientation and sensitivity.

The conductive loops 42 and 52 described above are single-turn loops. It will be appreciated that multi-turn coils or loops may be substituted for the single-turn loops described above, with suitable modification for creating direct coupling between the conductive loops and either the transponder chip 26 or the antenna 20. An example of such a multi-turn coil is the coil 102 shown in FIG. 7. The coil 102 has multiple turns one inside another in a generally spiral configuration, with a conductive shunt 106 provided across a non-conductive bridge 108, in order to enable direct electrical connection to either an antenna or a transponder chip. It will be appreciated that a multi-turn coil 102 may be constructed using multiple deposition steps for depositing first the main structure of the antenna 20, then the non-conductive bridge 106, and finally the conductive shunt 108.

It will be appreciated that a multi-turn coil may have any of a wide variety of configurations (e.g., shapes and sizes) and methods of construction. Coils with three of more turns or loops may be made with repetition of various suitable fabrication steps.

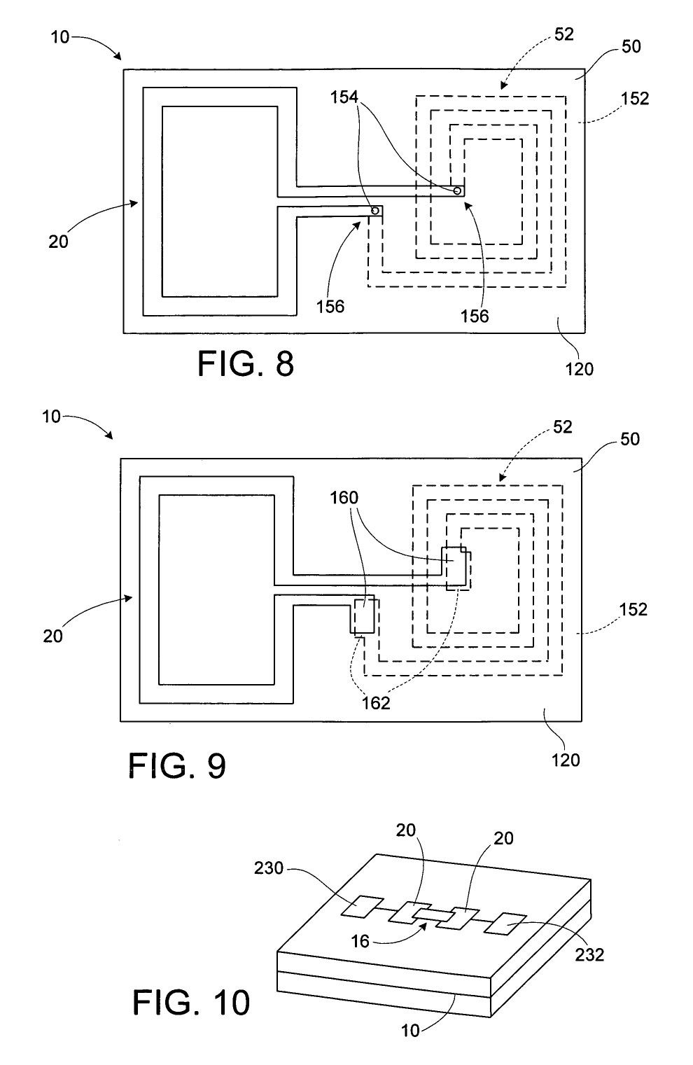

FIGS. 8 and 9 show alternative configurations for the antenna portion 14, with the antenna 20 on one face or major surface 120 of the antenna substrate 50, and the antenna portion conductive loop or coil 52 on a second face or major surface 152 of the antenna substrate 50. In the configuration shown in FIG. 8, the antenna 20 and the antenna portion conductive loop 52 are directly electrically coupled through conductive material 154 in holes 156 in the substrate 50. The holes 156 may be formed by punching or other suitable processes. The punching or other suitable processes may be used to both create the holes 156 and to cause some of the conductive material of the antenna 20 or of the antenna portion conductive loop 52, to be pushed into the holes 156.

The antenna portion 14 in FIG. 9 relies upon capacitive coupling to electrically couple the antenna 20 to the antenna portion conductive loop 52, across the antenna substrate 50. To provide for an enhanced capacitive coupling, the antenna 20 may have a pair of a capacitive elements 160 electrically coupled thereto, and the conductive loop 52 may have a pair of corresponding capacitive coupling elements 162 coupled thereto. The capacitive coupling elements 160 and 162 may be areas of electrically conductive material that serve as plates of a pair of parallel plate capacitors, using material from the antenna substrate 50 as an intervening dielectric. Thus each of the capacitive coupling elements 160 may be capacitively coupled to a corresponding capacitive coupling element 162. The thickness and material of the antenna substrate 50 may be selected to obtain the desired capacitive coupling between the antenna 20 and the conductive loop 42. Further details regarding capacitive coupling in RFID devices may be found in co-owned U.S. application Ser. No. 10/871,136, which is incorporated herein by reference in its entirety.

It will be appreciated that a variety of suitable antenna configurations, and a variety of different configurations of conductive loops (single turn or multiple turn) may be utilized with the antenna portion 14 shown in FIGS. 8 and 9, and described above. Further, it will be appreciated that the general principle of directly or capacitively coupling across a substrate may be utilized in configuring the interposer 16. That is, it will be appreciated that an alternative configuration of the interposer 16 may involve placing the transponder chip 26 on one side of the interposer substrate 40, and placing the conductive loop 42 on the other side of the interposer substrate 40.

It will be appreciated that the environment into which the RFID device (or other RFID devices disclosed herein) is introduced may to some extent impact the operation of the magnetic coupler 12. For example, placement of the RFID device 10 on a metal surface or on a carton containing metallic and/or magnetic objects, may cause some influence on the operation of the magnetic coupler 12. The magnetic coupler 12 may be configured to compensate to some extent for the influence of the environment into which it is placed. The RFID device 10 may include any of a variety of suitable compensation features or elements to compensate at least to some extent for various types of material upon which the RFID device 10 may be mounted. Such compensation elements may: 1) introduce an impedance matching network between the chip and antenna which impedance matches the two, maximizing power transfer between the chip and the antenna; and/or 2) change the effective length of antenna elements so that the antenna stays at the resonant condition. Further details regarding compensation elements may be found in U.S. Provisional Patent Application No. 60/537,483, filed Jan. 20, 2004, which is incorporated herein by reference in its entirety.

Further, the antenna 20 may have compensation features, such as those described in U.S. Provisional Patent Application No. 60/537,483, separate from and not directly associated with the magnetic coupler 12. These separate compensation elements of the antenna 20 may operate in conjunction with the magnetic coupler 12 to provide desirable response in a variety of environments. FIG. 10 schematically illustrates an antenna 20 with compensation elements 230 and 232.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. An RFID device comprising:
an antenna portion that includes an antenna;
an interposer having a transponder chip; and
a magnetic coupler magnetically coupling the antenna and the chip.

2. The device of claim 1,
wherein the magnetic coupler includes:
an antenna portion magnetic coupling element electrically coupled to the antenna; and
an interposer magnetic coupling element electrically coupled to the chip; and
wherein the coupling elements are parts of the magnetic coupler.

3. The device of claim 2,
wherein the antenna portion magnetic coupling elements is an antenna portion conductive loop; and
wherein the interposer magnetic coupling elements is an interposer conductive loop.

4. The device of claim 3, wherein the conductive loops are both single-turn loops.

5. The device of claim 3, wherein at least one of the conductive loops is a multi-turn coil.

6. The device of claim 5, wherein both of the conductive loops are multi-turn coils.

7. The device of claim 5, wherein the antenna portion conductive loop has a different number of turns than the interposer conductive loop, thereby making the magnetic coupler function as a transformer.

8. The device of claim 7, wherein the antenna portion conductive loop has more turns than the interposer conductive loop.

9. The device of claim 7, wherein the antenna portion conductive loop has fewer turns than the interposer conductive loop.

10. The device of claim 3, wherein at least one of the conductive loops has a substantially rectangular shape.

11. The device of claim 3, wherein at least one of the conductive loops has a substantially circular shape.

12. The device of claim 3, wherein the interposer conductive loop is directly electrically coupled to contacts of the chip.

13. The device of claim 12, wherein the interposer conductive loop provides a short circuit between the contacts of the chip.

14. The device of claim 3, wherein the antenna portion conductive loop is directly electrically coupled to the antenna.

15. The device of claim 14, wherein the antenna and the antenna portion conductive loop are a single structure made in a single process operation.

16. The device of claim 3, wherein the antenna portion conductive loop is capacitively coupled to contacts of the chip.

17. The device of claim 3, wherein the antenna portion includes an antenna substrate to which the antenna and the antenna portion coupling element are attached.

18. The device of claim 17, wherein the antenna and the antenna portion coupling element are on respective major surfaces of the antenna substrate, on opposite sides of the antenna substrate.

19. The device of claim 18, wherein the antenna and the antenna portion coupling element are directly electrically coupled together.

20. The device of claim 19, wherein the antenna and the antenna portion coupling element are directly electrically coupled together by conductive material in holes in the antenna substrate.

21. The device of claim 20, wherein the holes in the antenna substrate are punched holes.

22. The device of claim 18, wherein the antenna and the antenna portion coupling element are capacitively coupled together through the antenna substrate.

23. The device of claim 22, wherein the antenna and the antenna portion coupling element include respective pairs of capacitive coupling pads made of conductive material.

24. The device of claim 2, wherein the magnetic coupler includes a high permeability material operatively coupled to the magnetic coupling elements.

25. The device of claim 24, wherein the high permeability material is located at least in part in between the magnetic coupling elements.

26. The device of claim 24, wherein the high permeability material includes a ferrite.

27. The device of claim 24, wherein the high permeability material is part of an adhesive layer adhesively coupling the antenna portion and the interposer.

28. The device of claim 24, wherein the high permeability material is part of a coating covering the antenna portion coupling element.

29. The device of claim 24, wherein the high permeability material is part of a coating covering the interposer coupling element.

30. The device of claim 2, wherein the magnetic coupler compensates for effects of nearby objects on operation of the magnetic coupler.

31. The device of claim 30, wherein the antenna portion magnetic coupling element and the interposer magnetic coupling element cooperatively interact to compensate for effects of nearby objects on operation of the magnetic coupler.

32. The device of claim 1,
wherein the antenna portion includes an antenna substrate to which the antenna is attached; and
wherein the interposer is attached to the antenna substrate.
